(19) United States
(12) Patent Application Publication
(10) Pub. No.: US 2006/0240597 A1
(43) Pub. Date: Oct. 26, 2006

(54) Method for fabricating semiconductor device

(75) Inventor: Shunji Abe, Asakuchi-gun (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka-shi (JP)

(21) Appl. No.: 11/405,521

(22) Filed: Apr. 18, 2006

(30) Foreign Application Priority Data
Apr. 20, 2005 (JP) 2005-122785

(51) Int. Cl. H01L 21/00

(52) U.S. Cl. 438/118

(57) ABSTRACT

A method for fabricating a semiconductor device, which includes the steps of: removing an abnormal layer formed on a surface of a wiring substrate, the wiring substrate having a first interlayer insulating film formed on a semiconductor substrate, the first interlayer insulating film having a first recess in which a first wiring is formed via a first barrier layer; forming a first antidiffusion film and a second interlayer insulating film sequentially on the resulting substrate; forming a second recess in the second interlayer insulating film and the first antidiffusion film so as to expose the first wiring; forming a second barrier layer on the resulting substrate; forming a second wiring in the second recess, the second wiring being electrically connected to the first wiring; and forming a second antidiffusion film on the resulting substrate.

### CROSS-REFERENCE TO RELATED APPLICATION

This application is related to Japanese Patent Application No. 2005-122785 filed on Apr. 20, 2005, whose priority is claimed and the disclosure of which is incorporated by reference in its entirety.

### BACKGROUND OF THE INVENTION

1. Field of the Invention

The present invention relates to a method for fabricating a semiconductor device.

2. Description of Related Art

As semiconductor devices have become more integrated and more miniaturized, multilayer wirings (interconnects) have been miniaturized as well. For this reason, Cu has been used as a wiring material, because Cu has a lower resistance and a higher electromigration resistance than Al.

In general, Cu wirings are formed using a damascene method because there is no Cu compound having a low vapor pressure and it is therefore difficult to form Cu wirings by dry etching.

Referring now to FIG. 3A and FIG. 3B, a method for forming wirings using a damascene method is explained (see, for example, Japanese Unexamined Patent Publication No. 2003-109958).

As shown in FIG. 3A, wiring trenches are formed in an interlayer insulating film 53 formed on a semiconductor substrate 51 having a semiconductor element such as a transistor. In the trenches, a barrier layer 55 is formed, a conductor such as Cu is filled via the barrier layer 55, and an excessive conductor is removed by surface polishing so that wirings 57 are formed. Then, as shown in FIG. 3B, an antidiffusion film 59 is formed on a surface of a resulting substrate.

FIG. 4 shows the substrate in a state between the surface polishing and the formation of the antidiffusion film 59. Where the substrate is left in the state, a surface of the wirings 57 may be oxidized so as to form an oxide layer 57a, and/or the interlayer insulating film 53 may be deteriorated so as to form a deterioration layer 53a. Because the oxide layer 57a and the deterioration layer 53a may affect the yield or device characteristics, the layers are removed by a reduction process using NH₃ plasma before the formation of the antidiffusion film 59.

However, where the substrate is left for a long time in the state between the surface polishing and the antidiffusion film formation, the oxide layer 57a and the deterioration layer 53a may become too thick, making it difficult to sufficiently remove the layers by the reduction process.

### SUMMARY OF THE INVENTION

The present invention has been made in view of the above circumstances, and it provides a semiconductor device fabrication method which can surely remove a layer generated by surface abnormalities such as wiring oxidation or deterioration of an interlayer insulating film.

According to an aspect of the present invention, a method for fabricating a semiconductor device comprises the steps of: removing an abnormal layer formed on a surface of a wiring substrate, the wiring substrate having a first interlayer insulating film formed on a semiconductor substrate, the first interlayer insulating film having a first recess in which a first wiring is formed via a first barrier layer; forming a first antidiffusion film and a second interlayer insulating film sequentially on the resulting substrate; forming a second recess in the second interlayer insulating film and the first antidiffusion film so as to expose the first wiring; forming a second barrier layer on the resulting substrate; forming a second wiring in the second recess, the second wiring being electrically connected to the first wiring; and forming a second antidiffusion film on the resulting substrate.

According to the present invention, firstly, the abnormal layer is surely removed by surface polishing or the like. In that case, the first wiring is reduced in height, and therefore, it is necessary to compensate for the reduced height of the wiring. In order to meet such a need, the present invention forms another interlayer insulating film and then forms in this interlayer insulating film a second wiring which is electrically connected to the first wiring so that the second wiring compensates for the reduced height of the first wiring. Thus, according to the invention, it is possible to achieve higher yields and excellent device characteristics of wiring substrates which would otherwise have poor yields and device characteristics due to the abnormal layer formed deep inside the wiring substrates. The term “abnormal layer” refers to a layer having a surface abnormality, and examples of the “surface abnormality” includes abnormalities caused by various reasons such as oxidation of wirings, deterioration of interlayer insulating films, surface defects, abnormality in polishing, poor cleaning, poor processing and the like.

### BRIEF DESCRIPTION OF THE DRAWINGS

The present invention will become more fully understood from the detailed description given hereinbelow and the accompanying drawings which are given by way of illustration only, and thus are not limitative of the present invention and wherein:

FIG. 1A to FIG. 1F are cross-sectional views of semiconductor device fabrication steps according to an embodiment of the invention;

FIG. 2G to FIG. 2L are cross-sectional views of the semiconductor device fabrication steps according to the embodiment of the invention;

FIG. 3A and FIG. 3B are cross-sectional views of fabrication steps of a conventional semiconductor device; and

FIG. 4 is a cross-sectional view of a fabrication step of the conventional semiconductor device.

### DESCRIPTION OF THE PREFERRED EMBODIMENTS

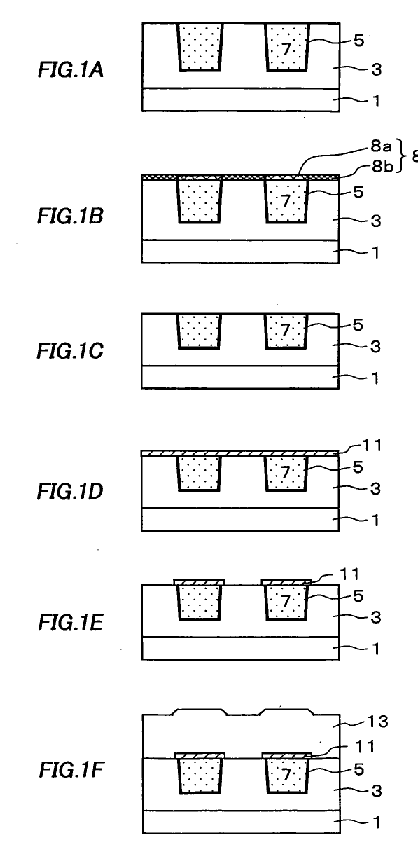

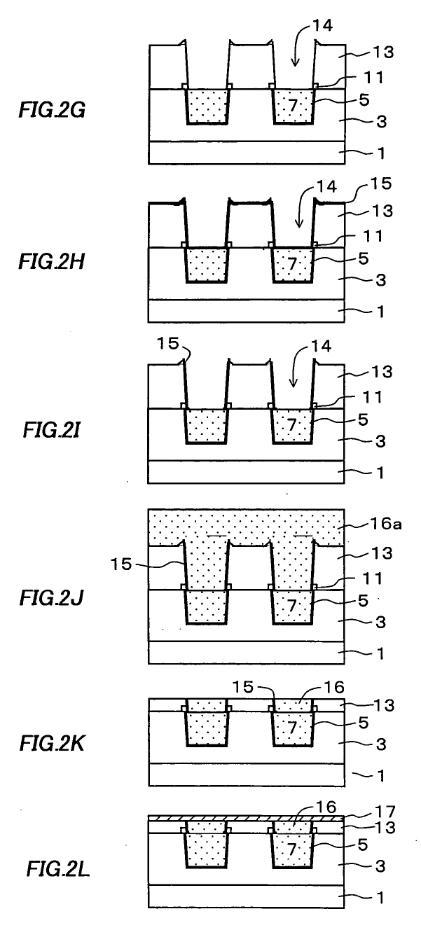

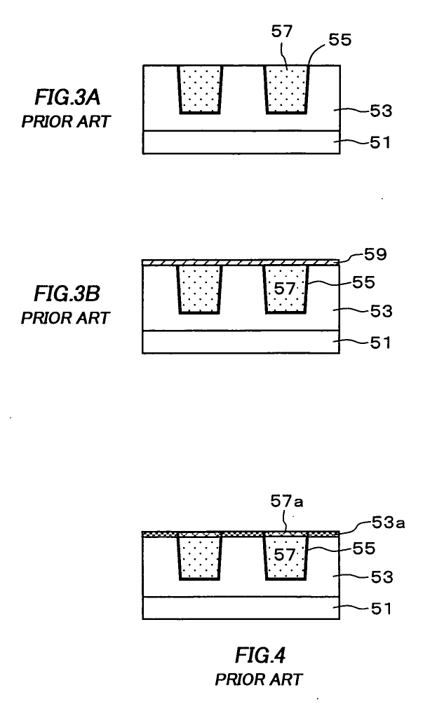

With reference to FIG. 1A to FIG. 1F and FIG. 2G to FIG. 2L, a method for fabricating a semiconductor device according to an embodiment of the present invention will be described below. FIG. 1A to FIG. 1F and FIG. 2G to FIG. 2L are cross-sectional views of semiconductor device fabrication steps according to the embodiment of the invention. The shapes, structures, film thicknesses, compositions and methods shown in the drawings and the following descriptions are given for the purpose of illustration, and the scope of the present invention is not limited to those.

1. Abnormal Layer Removal Step

As shown in FIG. 1A, a wiring substrate is prepared. The wiring substrate includes a semiconductor substrate 1 having a semiconductor element such as a transistor, a first interlayer insulating film 3 formed on the substrate 1, a first recess formed in the first interlayer insulating film 3, and a first wiring 7 formed in the first recess via a first barrier layer 5.

The type of the substrate is not limited, and for example, a Si substrate or a GaAs substrate may be used.

As the first interlayer insulating film 3, for example, a SiOF film, SiOC film, SiO₂ film or organic insulating film formed by a CVD method or a porous silica film formed by coating may be used. As to the first interlayer insulating film 3, the forming method, thickness, composition and constitution (whether the film is a single layer or multilayer) are not limited as long as the film can display its function.

The first recess can be formed using known photolithography and etching techniques. The depth of the recess (that is, the thickness of the first wiring 7) is set to, for example, 400 nm. In the present specification, the “recess” is comprised of, for example, a wiring trench or a via hole. As to the first recess, the forming method, shape and depth are not limited as long as the recess can accommodate the first barrier layer 5 and the first wiring 7.

The first barrier layer 5 may be formed of, for example, a nitride or oxide film of Ta, TiN, Ru or W, and may be formed by a sputtering, CVD or plating method or a combination of these. The first barrier layer 5 is preferably formed of a lamination layer of a TaN layer and a Ta layer, where the TaN layer is on the Ta layer, or a lamination layer of a TiN layer and a Ti layer, where the TiN layer is on the Ti layer. The first barrier layer 5 is preferably formed into a thickness of 3 nm to 50 nm, and for example, is formed into a thickness of 30 nm. The first barrier layer 5 may be made of any material having a function of preventing diffusion of a material of the first wiring 7 into the first interlayer insulating film 3. As to the barrier layer 5, the forming method, thickness, composition and constitution are not limited as long as the layer can display its function.

The first wiring 7 can be formed by, for example, forming a wiring material film made of Cu, Al, W or an alloy of these so as to fill the first recess by a sputtering, plating or CVD method, and removing an unnecessary portion by a CMP method (a single damascene method). As to the first wiring 7, the forming method, thickness, composition and constitution are not limited as long as the first wiring 7 can display its function as a wiring.

Where the wiring substrate is left for a long time, an abnormal layer 8 is formed on a surface of the substrate as shown in FIG. 1B. The abnormal layer 8 is composed of, for example, an oxide layer 8a formed by oxidation of the first wiring 7 and a deterioration layer 8b formed by deterioration of the interlayer insulating film. The deterioration layer 8b is formed by, for example, adsorption of water in the air onto a surface of the interlayer insulating film. As to the abnormal layer 8, the composition, thickness and formation conditions are not limited.

Following the above, the abnormal layer 8 is removed as shown in FIG. 1C. The removal method of the abnormal layer is not limited, and for example, surface polishing or etching back can be employed. The surface polishing may be carried out by a CMP method or the like. The etching back may be carried out by anisotropic etching. The removal thickness depends on the thickness of the abnormal layer 8, but is not limited as long as the abnormal layer 8 can be removed. The removal thickness may be, for example, 120 nm. When the abnormal layer 8 is removed, the thickness of the first wiring 7 is reduced and deviates from the design value. Therefore, in the following steps, a second wiring 16 electrically connected to the first wiring 7 is formed so that the second wiring 16 compensates for the reduced thickness of the first wiring 7 (see FIG. 2K).

2. First Antidiffusion Film Formation Step

Next, as shown in FIG. 1D, a first antidiffusion film 11 is formed on the resulting wiring substrate. The first antidiffusion film 11 is composed of a film having a function of preventing diffusion of atoms that constitute the first wiring 7 into a later-mentioned second interlayer insulating film 13. The first antidiffusion film 11 is formed of, for example, a SiN film, SiCN film, SiC film, a SiOC film or a multilayer film of at least two of these films. The first antidiffusion film 11 may be formed of a lamination film of a TiN layer and a Ti layer, where the TiN layer is on the Ti layer. The first antidiffusion film 11 may be formed by a CVD method or the like. The first antidiffusion film 11 is preferably formed into a thickness of 30 nm to 50 nm. As to the first antidiffusion film 11, the forming method, thickness, composition and constitution are not limited as long as the film can display the aforementioned function. The first antidiffusion film 11 may have a function of preventing oxidation of the first wiring 7 and serve as an etching stopper when forming a second recess.

Between the removal of the abnormal layer 8 and the formation of the first antidiffusion film 11, a step of subjecting the first wiring 7 to a reduction process may further be included. There is no limitation to the manner in which the reduction process is performed, and the reduction process may be performed by, for example, subjecting the wiring substrate to plasma of a reducing gas such as NH₃, H₂ or the like. The reduction process improves the adhesion of the first wiring 7 and the first antidiffusion film 11.

Next, as shown in FIG. 1E, the first antidiffusion film 11 is patterned so as to leave a portion covering the first wiring 7. The patterning method of the first antidiffusion film 11 is not limited. The patterning of the first antidiffusion film 11 may be performed by etching using a resist mask prepared by photolithography using the same photomask as that used in the first recess formation and a photoresist which is different in photosensitivity (whether the photosensitivity is positive or negative) from the photoresist used in the first recess formation. Alternatively, the patterning may be performed by using a photomask having an inverted pattern of the photomask used in the first recess formation and a photoresist having the same photosensitivity as that used in the first recess formation.

The first antidiffusion film 11 may be left without being patterned. In general, the antidiffusion film is formed of a material higher in dielectric constant than the interlayer insulating film. Therefore, the antidiffusion film is preferably patterned in order to prevent a decrease in interlayer capacitance. However, where the interlayer capacitance is not so important, the patterning may be excluded to reduce the number of steps.

3. Second Interlayer Insulating Film Formation Step

As shown in FIG. 1F, a second interlayer insulating film 13 is formed on the resulting substrate. The second interlayer insulating film 13 is preferably the same as the first interlayer insulating film 3 in material, forming method and the like, but may be different in one or more of these. The second interlayer insulating film 13 is preferably formed into a thickness not smaller than the removal thickness of the abnormal layer 8. The thickness of the second interlayer insulating film 13 is, for example, 300 nm.

4. Second Recess Formation Step

Subsequently, as shown in FIG. 2G, a second recess 14 is formed in the second interlayer insulating film 13 and the first antidiffusion film 11 so as to expose the first wiring 7. As to the second recess 14, the forming method is not limited. The second recess 14 may be formed by, for example, etching using a resist mask prepared by photolithography using the same photomask as that used in the patterning of the first antidiffusion film 11 and a photoresist which is different in photosensitivity from the photoresist used in the patterning of the first antidiffusion film 11. Alternatively, the formation of the second recess 14 may be performed by using a photomask having an inverted pattern of the photomask used in the patterning of the first antidiffusion film 11 and a photoresist having the same photosensitivity as the photomask used in the patterning of the first antidiffusion film 11.

The second recess 14 is preferably precisely aligned to the first wiring 7 so that the displacement between the second recess 14 and the first wiring 7 is within 10 nm.

5. Second Barrier Layer Formation Step

As shown in FIG. 2H, a second barrier layer 15 is formed on the resulting substrate. The second barrier layer 15 is preferably the same as the first barrier layer 5 in material, forming method, thickness and the like, but may be different in one or more of these.

Then, as shown in FIG. 21, the second barrier layer 15 on a bottom of the second recess 14 is removed. The removal method is not limited and may be performed by, for example, etching back the second barrier layer 15 by anisotropic etching. The removal of the second barrier layer 15 may be omitted and the second barrier layer may be left on the bottom of the second recess 14. In general, the barrier layer is made of a material higher in resistance than the wiring. Therefore, the removal is preferably performed in order to reduce the resistance of the entire wiring formed of the first wiring 7 and the second wiring 16. However, in the case where the resistance is not so important, the removal can be excluded to reduce the number of steps.

6. Second Wiring Formation Step

Subsequently, a second wiring 16 is formed in the second recess via the second barrier layer 15. The second wiring 16 is formed so that the second wiring 16 is electrically connected to the first wiring 7. The second wiring 16 can be formed by, for example, forming a wiring material film 16a made of Cu, Al, W or an alloy of these so as to fill the second recess 14 by a sputtering, plating or CVD method (FIG. 2J), and removing an unnecessary portion by a CMP method or the like (FIG. 2K). The wiring material film 16a is formed into a thickness of, for example, 700 nm. The second wiring 16 is preferably formed into a thickness equal to the removal thickness of the abnormal layer, but may be formed into a thickness of, for example, about 50% to 150% of the removal thickness. As to the second wiring 16, the forming method, thickness, composition and constitution are not limited as long as it functions as a wiring together with the first wiring 7.

7. Second Antidiffusion Film Formation Step

As shown in FIG. 2L, a second antidiffusion film 17 is formed on the resulting substrate. The second antidiffusion film 17 is preferably the same as the first antidiffusion film 11 in material, forming method, thickness and the like, but may be different in one or more of these.

Between the formation of the second wiring 16 and the formation of the second antidiffusion film 17, a step of subjecting the second wiring 16 to a reduction process may further be included. The conditions and effect of the reduction process are as described above in the section “2. First Antidiffusion Film Formation Step”.

With the above steps, a semiconductor device in which the abnormal layer 8 is removed and the reduction in thickness of the first wiring 7 is compensated by the second wiring 16 is fabricated.

In the embodiment shown above, only the removal of the abnormal layer 8 is performed. However, in the case where the abnormal layer 8 is found to be existing after the formation of the second antidiffusion film 17 or a layer thereabove, removal of the second antidiffusion film 17 or the layer thereabove may be performed before the removal of the abnormal layer 8.

In the embodiment shown above, the explanation is given with respect to a single damascene structure. However, the present invention is applicable to a dual damascene structure and a plug for a via hole connecting upper and lower wirings.

Where the abnormal layer is formed again after the formation of the second wiring, the present invention can be employed again.

Finally, preferred combinations of materials are shown in Table 1.

TABLE 1

| | 1st and 2nd | | | |
|---|---|---|---|---|
| | Interlayer | | | 1st and 2nd |
| | Insulating | 1st and 2nd | 1st and 2nd | Antidiffusion |
| No. | Films | Barrier Layers | Wirings | Films |
| 1 | SiOC | TaN/Ta | Cu | SiCN |
| 2 | SiOF | TaN/Ta | Cu | SiN |
| 3 | SiO₂ | TaN/Ta | Cu | SiN |
| 4 | SiO₂ | TiN/Ti | W or Al | TiN/Ti |

In Table 1, “TaN/Ta” denotes a lamination layer of a TaN layer and a Ta layer, where the TaN layer is on the Ta layer, and “TiN/Ti” denotes a lamination layer of a TiN layer and a Ti layer, where the TiN layer is on the Ti layer.

Among combinations shown in Table 1, the combination No. 1 is most preferable.

The invention thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for fabricating a semiconductor device, the method comprising the steps of:
removing an abnormal layer formed on a surface of a wiring substrate, the wiring substrate having a first interlayer insulating film formed on a semiconductor substrate, the first interlayer insulating film having a first recess in which a first wiring is formed via a first barrier layer;
forming a first antidiffusion film and a second interlayer insulating film sequentially on the resulting substrate;
forming a second recess in the second interlayer insulating film and the first antidiffusion film so as to expose the first wiring;
forming a second barrier layer on the resulting substrate;
forming a second wiring in the second recess, the second wiring being electrically connected to the first wiring; and
forming a second antidiffusion film on the resulting substrate.

2. The method according to claim 1, further comprising the step of subjecting the first wiring to a reduction process, between the removal of the abnormal layer and the formation of the first antidiffusion film.

3. The method according to claim 1, further comprising the step of patterning the first antidiffusion film so as to leave a portion covering the first wiring, between the formation of the first antidiffusion film and the formation of the second interlayer insulating film.

4. The method according to claim 1, further comprising the step of removing the second barrier layer on a bottom of the second recess, between the formation of the second barrier layer and the formation of the second wiring.

5. The method according to claim 1, further comprising the step of subjecting the second wiring to a reduction process, between the formation of the second wiring and the formation of the second antidiffusion film.

6. The method according to claim 3, wherein the second recess is formed by etching using a resist mask prepared by photolithography using the same photomask as that used in the patterning of the first antidiffusion film and a photoresist which is different in photosensitivity from the photoresist used in the patterning of the first antidiffusion film.

7. The method according to claim 1, wherein the second wiring is formed into a thickness equal to 50% to 150% of a removal thickness of the abnormal layer.

8. The method according to claim 1, wherein the first and second interlayer insulating films are formed of SiOC, the first and second barrier layers are formed of lamination layers of a TaN layer and a Ta layer wherein the TaN layer is on the Ta layer, the first and second wirings are formed of Cu, and the first and second antidiffusion films are formed of SiCN.
